(19) United States
(12) Patent Application Publication
(10) Pub. No.: US 2025/0275376 A1
(43) Pub. Date: Aug. 28, 2025

(54) DISPLAY APPARATUS

(71) Applicant: LG Display Co., Ltd., Seoul (KR)

(72) Inventors: SeongHan HWANG, Goyang-si (KR); SunWoo KIM, Gunpo-si (KR); KyungKook JANG, Goyang-si (KR)

(21) Appl. No.: 19/017,054

(22) Filed: Jan. 10, 2025

(30) Foreign Application Priority Data
Feb. 23, 2024 (KR) 10-2024-0026305

(51) Int. Cl. H10K 59/122; H10K 50/19

(52) U.S. Cl. CPC H10K 59/122; H10K 50/19

(57) ABSTRACT

Provided is a display apparatus. The display apparatus includes a substrate on which a plurality of sub pixels are defined. The display apparatus includes a plurality of light emitting diodes each of which is disposed in each of the plurality of sub pixels and includes a first electrode, an emission unit, and a second electrode. The display apparatus includes a bank which is disposed on one side of the first electrode on the substrate to expose a part of the first electrode. The display apparatus includes a plurality of first hollow (e.g., hollow spheres) disposed on the bank and the emission unit and the second electrode are disposed on the plurality of first hollows sequentially.

### CROSS-REFERENCE TO RELATED APPLICATIONS

This application claims the priority of Korean Patent Application No. 10-2024-0026305 filed on Feb. 23, 2024, in the Korean Intellectual Property Office, the disclosure of which is incorporated herein by reference.

### BACKGROUND

### Technical Field

The present disclosure relates to a display apparatus.

### Description of the Related Art

Recently, as it enters an information era, a display field which visually expresses electrical information signals has been rapidly developed and in response to this, various display apparatuses having excellent performances such as thin-thickness, light weight, and low power consumption have been developed.

Among various display apparatus, an organic light emitting display apparatus is a self-emitting display apparatus so that a separate light source is not necessary, which is different from the liquid crystal display apparatus. Therefore, the organic light emitting display apparatus may be manufactured to have a light weight and a small thickness. Further, since the organic light emitting display apparatus is driven at a low voltage, it is advantageous not only in terms of power consumption, but also in terms of the color implementation, the response speed, the viewing angle, and the contrast ratio (CR), so that the organic light emitting display apparatus is being studied as next generation displays.

### BRIEF SUMMARY

Various embodiments of the present disclosure provide a display apparatus which improves leakage of current to adjacent sub pixels from each of a plurality of sub pixels.

Various embodiments of the present disclosure provide a display apparatus which improves degradation of a color characteristic in an adjacent sub pixel by improving a leakage current.

Technical benefits of the present disclosure are not limited to the above-mentioned benefits, and other benefits, which are not mentioned above, can be clearly understood by those skilled in the art from the following descriptions.

According to an embodiment of the present disclosure, a display apparatus includes a substrate on which a plurality of sub pixels are defined; a plurality of light emitting diodes, each of which is disposed in each of the plurality of sub pixels and includes a first electrode, an emission unit, and a second electrode; a bank which is disposed on one side of the first electrode on the substrate to expose a part of the first electrode; and a plurality of first hollow (hollow spheres) disposed on the bank and the emission unit and the second electrode are disposed on the plurality of first hollows sequentially.

Other detailed matters of the exemplary embodiments are included in the detailed description and the drawings.

According to the present disclosure, the leakage of current to adjacent sub pixels from each of the plurality of sub pixels can be improved.

According to the present disclosure, emission of unintended light emitting diodes due to a leakage current is reduced or minimized to improve color reproduction rate.

According to the present disclosure a hollow is disposed in a bank to scatter light which is incident as external light, thereby reducing or minimizing visual recognition of the external light.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a view of a display apparatus according to an exemplary embodiment of the present disclosure;

FIG. 2 is a plan view illustrating a part of an active area according to an exemplary embodiment of the present disclosure;

FIG. 3 is a cross-sectional view taken along A-A′ of FIG. 2;

FIG. 4 is an enlarged cross-sectional view of an area B of FIG. 3;

FIG. 5 is an enlarged cross-sectional view of an area C of FIG. 3;

FIG. 6 is an enlarged cross-sectional view of a display apparatus according to another exemplary embodiment of the present disclosure;

FIG. 7 is an enlarged cross-sectional view of a display apparatus according to still another exemplary embodiment of the present disclosure;

FIG. 8 is an enlarged cross-sectional view of a display apparatus according to still another exemplary embodiment of the present disclosure;

FIG. 9 is an enlarged cross-sectional view of a display apparatus according to still another exemplary embodiment of the present disclosure;

FIGS. 10A to 10D are enlarged cross-sectional views of a display apparatus according to various exemplary embodiments of the present disclosure;

FIGS. 11A to 11C are process cross-sectional views for explaining a manufacturing method of a display apparatus according to an exemplary embodiment of the present disclosure; and

FIGS. 12A to 12C are process cross-sectional views for explaining a manufacturing method of a display apparatus according to another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

The features of various embodiments of the present disclosure can be partially or entirely adhered to or combined with each other and can be interlocked and operated in technically various ways, and the embodiments can be carried out independently of or in association with each other.

Hereinafter, a display apparatus according to exemplary embodiments of the present disclosure will be described in detail with reference to accompanying drawings.

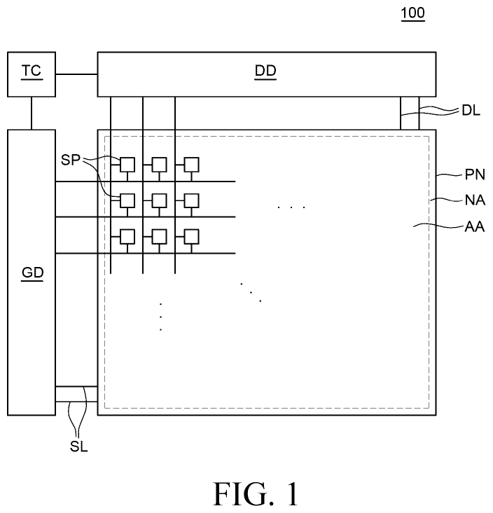

FIG. 1 is a view of a display apparatus according to an exemplary embodiment of the present disclosure; In FIG. 1, for the convenience of description, among various components of the display apparatus 100, only a display panel PN, a gate driver GD, a data driver DD, and a timing controller TC are illustrated.

Referring to FIG. 1, the display apparatus 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD converts image data input from the timing controller TC into a data voltage using a reference gamma voltage in accordance with a plurality of data control signals supplied from the timing controller TC. The data driver DD may supply the converted data voltage to the plurality of data lines DL.

The timing controller TC aligns image data input from the outside to supply the image data to the data driver DD. The timing controller TC may generate a gate control signal and a data control signal using synchronization signals input from the outside, such as a dot clock signal, a data enable signal, and horizontal/vertical synchronization signals. The timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. In the display panel PN, the plurality of scan lines SL and the plurality of data lines DL intersect each other and the plurality of sub pixels SP is connected to the scan lines SL and the data lines DL, respectively. In addition, even though it is not illustrated in the drawing, each of the plurality of sub pixels SP is connected to a high potential power line, a low potential power line, and a reference line.

In the display panel PN, an active area AA and a non-active area NA enclosing the active area AA may be defined.

The active area AA is an area in which images are displayed in the display apparatus 100. In the active area AA, a plurality of sub pixels SP which configures a plurality of pixels and a circuit for driving the plurality of sub pixels SP may be disposed. The plurality of sub pixels SP is a minimum unit which configures the active area AA and n sub pixels SP form one pixel.

In each of the plurality of sub pixels SP, a light emitting diode and a thin film transistor for driving the light emitting diode may be disposed. The plurality of light emitting diodes may be defined in different manners depending on the type of the display panel PN. For example, when the display panel PN is an organic light emitting display panel, the light emitting diode 120 may be an organic light emitting diode (OLED).

A placement, a number, and a color combination of the plurality of sub pixels SP may be changed in various ways depending on the designs, but are not limited thereto.

In the active area AA, a plurality of signal lines which transmits various signals to the plurality of sub pixels SP is disposed. For example, the plurality of signal lines includes a plurality of data lines DL which supplies a data voltage to each of the plurality of sub pixels SP and a plurality of scan lines SL which supplies a gate voltage to each of the plurality of sub pixels SP. The plurality of scan lines SL extends to one direction in the active area AA to be connected to the plurality of sub pixels SP and the plurality of data lines DL extends to a direction different from the one direction in the active area AA to be connected to the plurality of sub pixels SP. In addition, in the active area AA, a low potential power line and a high potential power line may be further disposed, but are not limited thereto.

The non-active area NA is an area where images are not displayed so that the non-active area NA may be defined as an area extending from the active area AA. In the non-active area NA, a link line which transmits a signal to the sub pixel SP of the active area AA, a pad electrode, or a driving IC, such as a gate driver IC or a data driver IC, may be disposed, but is not limited thereto.

The display apparatus 100 may further include various additional elements to generate various signals or drive the sub pixel SP in the active area AA. The additional elements for driving the sub pixels SP may include an inverter circuit, a multiplexer, or an electro static discharge circuit (ESD). The display apparatus 100 may also include an additional element associated with a function other than the sub pixel (SP) driving function. For example, the display apparatus 100 may further include additional elements which provide a touch sensing function, a user authentication function (for example, fingerprint recognition), a multilevel pressure sensing function, or a tactile feedback function. The above-mentioned additional elements may be located in an external circuit which is connected to the non-active area NA and/or the connecting interface.

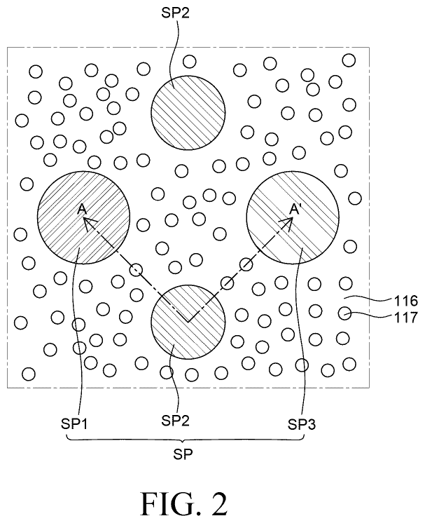

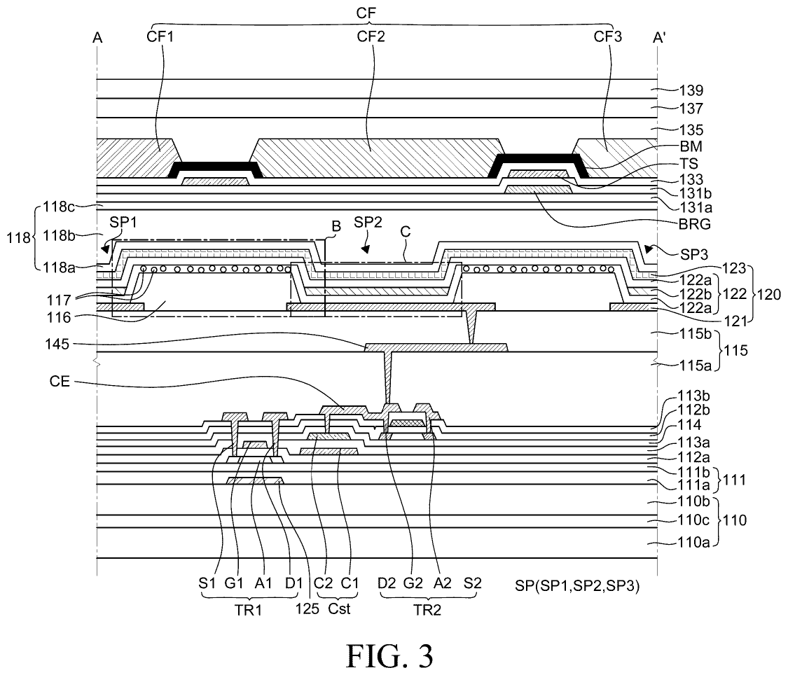

Hereinafter, the active area AA of the display apparatus 100 will be described in more detail with reference to FIGS. 2 and 3 together.

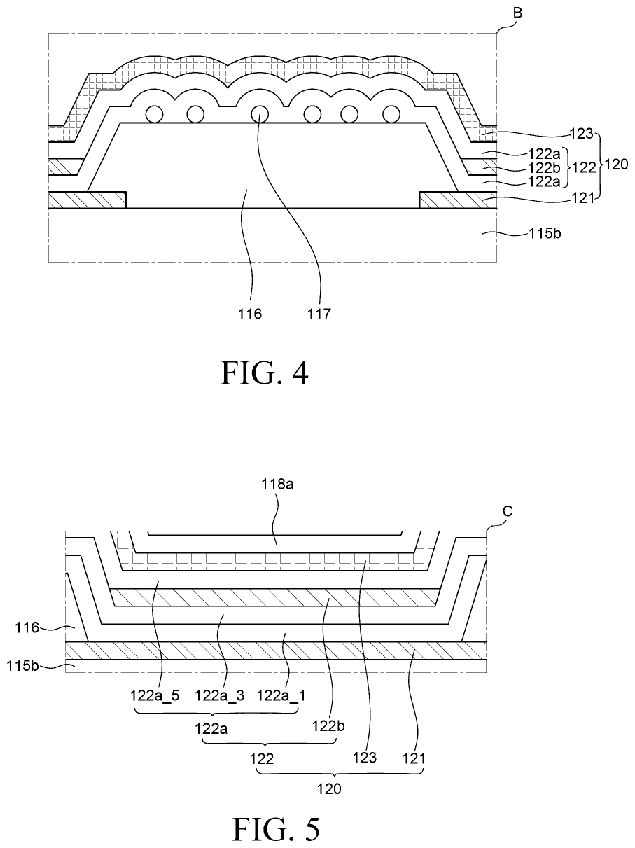

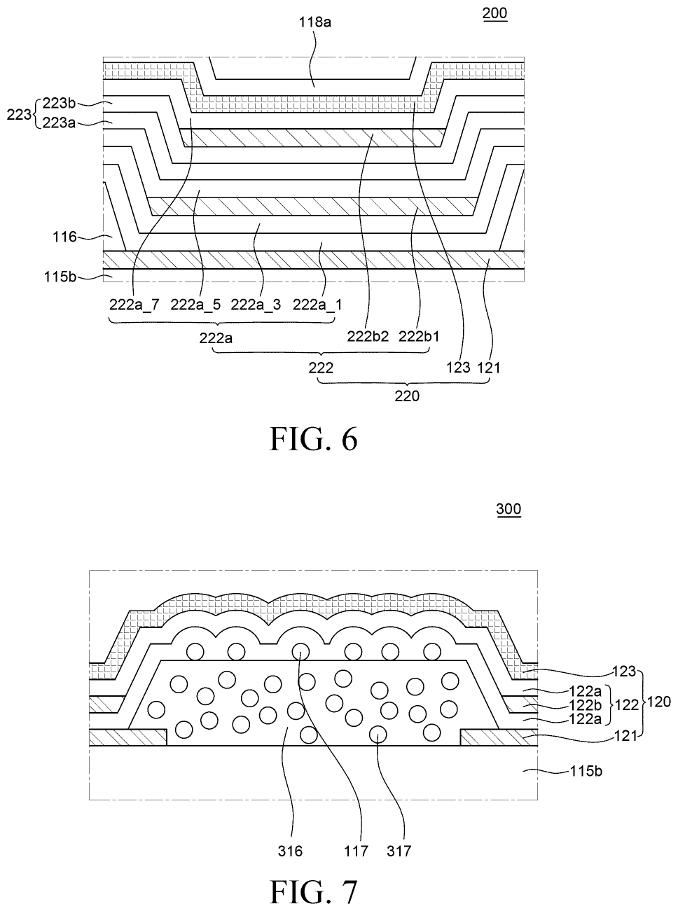

FIG. 2 is a plan view illustrating a part of an active area according to an exemplary embodiment of the present disclosure. FIG. 3 is a cross-sectional view taken along A-A′ of FIG. 2. FIG. 4 is an enlarged cross-sectional view of an area B of FIG. 3. FIG. 5 is an enlarged cross-sectional view of an area C of FIG. 3. For the convenience of illustration, in FIG. 2, only a plurality of sub pixels SP, a bank 116, and a first hollow 117, among various components of the display apparatus 100, are illustrated. Further, in FIG. 4, for the convenience of illustration, an encapsulation unit 118 disposed above the second electrode 123 is not illustrated.

First, referring to FIG. 2, the active area AA is formed by a plurality of sub pixels SP and each of the plurality of sub pixels SP is an individual unit which emits light and a light emitting diode is disposed in each of the plurality of sub pixels SP. The plurality of sub pixels SP includes a first sub pixel SP1, a second sub pixel SP2, and a third sub pixel SP3, which emit different color light. For example, the first sub pixel SP1 is a red sub pixel, the second sub pixel SP2 is a green sub pixel, and the third sub pixel SP3 is a blue sub pixel, but it is not limited thereto. That is, a color, a configuration, and a placement of light implemented in each of the plurality of sub pixels SP may vary depending on the design, but are not limited thereto.

Referring to FIG. 3, a display panel PN of a display apparatus 100 according to an exemplary embodiment of the present disclosure includes a substrate 110, a first buffer layer 111, a first thin film transistor TR1, a second thin film transistor TR2, a first gate insulating layer 112a, a first interlayer insulating layer 113a, a second buffer layer 114, a second gate insulating layer 112b, a second interlayer insulating layer 113b, a connection electrode CE, a first planarization layer 115a, a second planarization layer 115b, an auxiliary electrode 145, a bank 116, a first hollow 117, a first electrode 121, an emission layer 122, a second electrode 123, an encapsulation unit 118, a touch sensing unit, and a plurality of color filters CF. Wherein, the combination of the first planarization layer 115a and the second planarization layer 115b is called a planarization layer 115.

The substrate 110 serves to support and protect components of the display apparatus 100 disposed thereabove. The plurality of sub pixels SP is defined on the substrate 110.

The substrate 110 is a component for supporting various components included in the display apparatus 100 and may be formed of an insulating material. The substrate 110 includes a first substrate 110a, a second substrate 110b, and an interlayer insulating film 110c. The interlayer insulating film 110c may be disposed between the first substrate 110a and the second substrate 110b. As described above, the substrate 110 is configured by the first substrate 110a, the second substrate 110b, and the interlayer insulating film 110c to suppress the moisture permeation. For example, the first substrate 110a and the second substrate 110b may be polyimide (PI) substrates and the interlayer insulating film 110c may be formed of a single layer of silicon nitride (SiNₓ) or silicon oxide (SiOₓ) or multiple layers thereof.

A light shielding layer 125 is disposed on the substrate 110.

The first buffer layer 111 is disposed on the substrate 110 while covering the light shielding layer 125. Specifically, a multi-buffer layer 111a is disposed on the substrate 110 while covering the light shielding layer 125 and an active buffer layer 110b is disposed on the multi-buffer layer 111a.

The multi-buffer layer 111a delays diffusion of the moisture or oxygen permeating the substrate 110 and includes at least any one of silicon nitride (SiNₓ) and silicon oxide (SiOₓ).

The active buffer layer 111b protects a first active layer A1 and blocks various types of defects introduced from the substrate 110. For example, the active buffer layer 111b includes at least any one of silicon nitride (SiNₓ) and silicon oxide (SiOₓ).

The first thin film transistor TR1 may be disposed on the first buffer layer 111. The first thin film transistor TR1 may include a first active layer A1, a first gate electrode G1, a first source electrode S1, and a first drain electrode D1. Here, depending on the design of the pixel circuit, the first source electrode S1 may serve as a first drain electrode and the first drain electrode D1 may serve as a first source electrode.

The first active layer A1 is disposed on the first buffer layer 111 so as to overlap the light shielding layer 125. The first active layer A1 may include amorphous silicon or polycrystalline silicon. For example, the first active layer A1 may include a low-temperature polycrystalline silicon LTPS. For example, the polysilicon material has a high mobility (100 cm²/Vs or higher) to have low energy consumption and excellent reliability. In the present disclosure, an amorphous silicon (a-Si) material is deposited on the first buffer layer 111 and a dehydrogenation process and a crystallization process are performed to form polycrystalline silicon and the polycrystalline silicon is patterned to form the first active layer A1. Here, the first active layer A1 includes a first channel region in which a channel is formed when the first thin film transistor T1 is driven and a first source region and a first drain region on both sides of the first channel region. The first source region refers to a part of the first active layer A1 which is connected to the first source electrode S1 and the first drain region refers to a part of the first active layer A1 which is connected to the first drain electrode D1. For example, the first source region and the first drain region are configured by ion-doping (impurity doping) of the first active layer A1. The first source region and the first drain region may be generated by doping ions into the polycrystalline silicon material and the first channel region may refer to a part in which the ions are not doped, but the polycrystalline silicon material remains.

The first gate insulating layer 112a is disposed on the first active layer A1. The first gate insulating layer 112a may be configured by a single layer of silicon nitride (SiNₓ) or silicon oxide (SiOₓ) or a multilayer thereof. In the first gate insulating layer 112a, a contact hole through which the first source electrode S1 and the first drain electrode D1 of the first thin film transistor TR1 are connected to the first source region and the first drain region of the first active layer A1 of the first thin film transistor TR1, respectively, may be formed.

The first gate electrode G1 of the first thin film transistor TR1 and a first capacitor electrode C1 of the storage capacitor Cst may be disposed on the first gate insulating layer 112a.

At this time, the first gate electrode G1 and the first capacitor electrode C1 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. The first gate electrode G1 may be formed on the first gate insulating layer 112a so as to overlap the first channel region of the first active layer A1 of the first thin film transistor TR1.

The first capacitor electrode C1 may be omitted based on a driving characteristic of the display apparatus 100 and a structure and a type of the thin film transistor. The first gate electrode G1 and the first capacitor electrode C1 may be formed by the same process. Further, the first gate electrode G1 and the first capacitor electrode C1 may be formed of the same material on the same layer.

The first interlayer insulating layer 113a may be disposed above the first gate insulating layer 112a, the first gate electrode G1, and the first capacitor electrode C1. The first interlayer insulating layer 113a may be configured by a single layer of silicon nitride (SiNₓ) or silicon oxide (SiOₓ) or a multilayer thereof. In the first insulating layer 113a, a contact hole for exposing the first source region and the first drain region of the first active layer A1 of the first thin film transistor TR1 may be formed.

A second capacitor electrode C2 of the storage capacitor Cst may be disposed on the first interlayer insulating layer 113a. The second capacitor electrode C2 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. The second capacitor electrode C2 may be formed on the first interlayer insulating layer 113a so as to overlap the first capacitor electrode C1. Further, the second capacitor electrode C2 may be formed of the same material as the first capacitor electrode C1. The second capacitor electrode C2 may be omitted based on a driving characteristic of the display apparatus 100 and a structure and a type of the thin film transistor.

The second buffer layer 114 may be disposed on the first interlayer insulating layer 113a and the second capacitor electrode C2. The second buffer layer 114 may be configured by a single layer of silicon nitride (SiNₓ) or silicon oxide (SiOₓ) or a multi-layer thereof. A contact hole for exposing the first source region and the first drain region of the first active layer A1 of the first thin film transistor TR1 may be formed in the second buffer layer 114. Further, in the second buffer layer 114, a contact hole for exposing the second capacitor electrode C2 of the storage capacitor Cst may be formed.

The second buffer layer 114 may be formed by a multiple layer, but is not limited thereto.

The second active layer A2 of the second thin film transistor TR2 may be disposed on the second buffer layer 114. Here, the second thin film transistor TR2 may include a second active layer A2, a second gate insulating layer 112b, a second gate electrode G2, a second source electrode S2, and a second drain electrode D2. Here, depending on the design of the pixel circuit, the second source electrode S2 may serve as a drain electrode and the second drain electrode D2 may serve as a source electrode.

Further, the second active layer A2 includes a second channel region in which a channel is formed when the second thin film transistor TR2 is driven and a second source region and a second drain region on both sides of the second channel region. The second source region refers to a part of the second active layer A2 which is connected to the second source electrode S2 and the second drain region refers to a part of the second active layer A2 which is connected to the second drain electrode D2.

The second active layer A2 may be formed of an oxide semiconductor. The oxide semiconductor material has a larger band gap as compared with a silicon material so that electrons may not jump over the band gap in an off state. Therefore, the oxide semiconductor material has a low off-current. Further, due to the small off-current, a magnitude of an auxiliary capacitance may be reduced so that the oxide semiconductor may be appropriate for a high resolution display element. For example, the second active layer A2 may be formed of various metal oxides such as indium-gallium-zinc-oxide (IGZO). Here, the description was made under assumption that the second active layer A2 of the second thin film transistor TR2 is configured by IGZO, among various metal oxides, but it is not limited thereto. Therefore, the second active layer A2 may be formed of another metal oxide such as indium-zinc-oxide (IZO), indium-gallium-tin-oxide (IGTO), or indium-gallium-oxide (IGO), rather than IGZO.

The second active layer A2 may be formed by depositing the metal oxide on the second buffer layer 114, performing a heat treatment for stabilization, and then patterning the metal oxide.

The second gate insulating layer 112b may be disposed on the entire substrate 110 including the second active layer A2. For example, the second gate insulating layer 112b may be configured by a single layer of silicon nitride (SiNₓ) or silicon oxide (SiOₓ) or a multilayer thereof.

The second gate electrode G2 may be disposed on the second gate insulating layer 112b.

The second gate electrode G2 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof.

For example, a metal material is formed on the second gate insulating layer 112b, a photoresist pattern is formed on the metal material, and then the metal material is wet-etched using the photoresist pattern as a mask to form the second gate electrode G2. As a wet etchant for etching the metal material, a material which selectively etches molybdenum (Mo), copper (Cu), titanium (Ti), aluminum (Al), chrome (Cr), gold (Au), nickel (Ni), and neodymium (Nd) or an alloy thereof which configures the metal material but does not etch the insulating material may be used.

The second interlayer insulating layer 113b is disposed on the second gate insulating layer 112b and the second gate electrode G2. A contact hole for exposing the first active layer A1 of the first thin film transistor TR1 and the second active layer A2 of the second thin film transistor TR2 may be formed in the second interlayer insulating layer 113b. For example, a contact hole for exposing the first source region and the first drain region of the first active layer A1 of the first thin film transistor TR1 may be formed in the second interlayer insulating layer 113b. A contact hole for exposing the second source region and the second drain region of the second active layer A2 of the second thin film transistor TR2 may be formed in the second interlayer insulating layer 113b.

The second interlayer insulating layer 113b may be configured as a single layer of silicon nitride (SiNₓ) or silicon oxide (SiOₓ) or a multi-layer thereof.

The connection electrode CE, the first source electrode S1 and the first drain electrode D1 of the first thin film transistor TR1 and the second source electrode S2 and the second drain electrode D2 of the second thin film transistor TR2 may be disposed on the second interlayer insulating layer 113b.

The connection electrode CE may be electrically connected to the second drain electrode D2 of the second thin film transistor TR2. Further, the connection electrode CE may be electrically connected to the second capacitor electrode C2 of the storage capacitor Cst through the contact holes formed in the second buffer layer 114 and the second interlayer insulating layer 113b. That is, the connection electrode CE may serve to electrically connect the second capacitor electrode C2 of the storage capacitor Cst and the second drain electrode D2 of the second thin film transistor TR2 to each other.

Here, the first source electrode S1 and the first drain electrode D1 of the first thin film transistor TR 1 may be connected to the first active layer A1 of the first thin film transistor TR1 through the contact holes formed in the first gate insulating layer 112a, the first interlayer insulating layer 113a, the second buffer layer 114, and the second interlayer insulating layer 113b.

The second source electrode S2 and the second drain electrode D2 of the second thin film transistor TR2 may be connected to the second active layer A2 through the contact hole formed in the second interlayer insulating layer 113b.

The connection electrode CE, the first source electrode S1 and the first drain electrode D1 of the first thin film transistor TR1 and the second source electrode S2 and the second drain electrode D2 of the second thin film transistor TR2 may be formed of the same material by the same process.

For example, the connection electrode CE, the first source electrode S1 and the first drain electrode D1 of the first thin film transistor TR1 and the second source electrode S2 and the second drain electrode D2 of the second thin film transistor TR2 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. For example, the connection electrode CE, the first source electrode S1 and the first drain electrode D1 of the first thin film transistor TR1 and the second source electrode S2 and the second drain electrode D2 of the second thin film transistor TR2 may be formed of a triple layered structure of titanium (Ti)/aluminum (Al)/titanium (Ti), but are not limited thereto.

The connection electrode CE may be integrally formed to be connected to the second drain electrode D2 of the second thin film transistor TR2, but is not limited thereto.

The first planarization layer 115a may be disposed above the connection electrode CE, the first source electrode S1 and the first drain electrode D1 of the first thin film transistor TR1, the second source electrode S2 and the second drain electrode D2 of the second thin film transistor TR2, and the second interlayer insulating layer 113b.

The first planarization layer 115a may be an organic layer which planarizes and protects upper portions of the first thin film transistor TR1 and the second thin film transistor TR2. For example, the first planarization layer 115a may be formed of an organic material such as acryl resin, epoxy resin, phenolic resin, polyamide resin, or polyimide resin.

The auxiliary electrode 145 may be disposed on the first planarization layer 115a. The auxiliary electrode 145 may be connected to the second drain electrode D2 of the second thin film transistor TR2 through the contact hole of the first planarization layer 115a. The auxiliary electrode 145 may serve to electrically connect the second thin film transistor TR2 and the first electrode 121 with each other. The auxiliary electrode 145 may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. The auxiliary electrode 145 may be formed of the same material as the second source electrode S2 and the second drain electrode D2 of the second thin film transistor TR2.

The second planarization layer 115b may be disposed above the auxiliary electrode 145 and the first planarization layer 115a. For example, the second planarization layer 115b may be formed of an organic material such as acryl resin, epoxy resin, phenolic resin, polyamide resin, and polyimide resin.

The plurality of light emitting diodes 120 is disposed in each of the plurality of sub pixels SP on the second planarization layer 115b. The light emitting diode 120 includes a first electrode 121, an emission unit 122, and a second electrode 123.

The first electrode 121 is disposed on the second planarization layer 115b. At this time, the first electrode 121 may be electrically connected to the auxiliary electrode 145 through the contact hole provided in the second planarization layer 115b. The first electrode 121 may be an anode and supplies holes to the emission unit 122 so that the first electrode 121 may be formed of a conductive material having a high work function.

When the display apparatus 100 is a top emission type in which light emitted from the light emitting diode 120 is emitted above the substrate SUB on which the light emitting diode 120 is disposed, the first electrode 121 may include a reflective layer and a transparent conductive layer on the reflective layer. The transparent conductive layer may be formed of, for example, transparent conductive oxide such as indium tin oxide (ITO) or indium zinc oxide (IZO) and the reflective layer may be formed of, for example, silver (Ag), aluminum (Al), gold (Au), molybdenum (Mo), tungsten (W), chrome (Cr), or an alloy thereof.

The bank 116 may be disposed on one side or on an end of the first electrode 121. A part of the bank 116 corresponding to an emission area of the sub pixel may be open. A part of the first electrode 121 may be exposed through the open part of the bank 116 (hereinafter, referred to as an open area). The bank 116 may be an insulating material disposed on an edge or a border of the first electrode 121. For example, the bank 116 may be formed of a transparent organic insulating material, such as benzocyclobutene resin, acrylic resin or imide resin, but is not limited thereto.

Referring to FIGS. 3 and 4, a plurality of first hollows 117 is disposed between the plurality of sub pixels SP. The plurality of first hollows 117 is disposed on the bank 116 between the plurality of sub pixels SP. Here, the first hollow 117 means an empty space. The first hollow 117 is a hollow sphere. Specifically, the bank 116 includes a top surface and a side surface and the plurality of first hollows 117 is disposed on the top surface of the bank 116. The bank 116 has a surface roughness Ra by the first hollow 117. Moreover, the surface roughness of the bank 116 may be increased or decreased according to a size and a placement amount of the first hollow 117. That is, the larger the size and the placement amount of the first hollow 117, the higher the surface roughness of the bank 116. In contrast, the smaller the size and the placement amount of the first hollow 117, the lower the surface roughness of the bank 116.

The plurality of first hollows 117 which is disposed so as to enclose each of the plurality of sub pixels SP is irregularly disposed on the bank 116. However, the placement and the number of the plurality of first hollows 117 are not limited thereto. In the meantime, the size of the plurality of first hollows 117 may have a diameter in the unit of micrometers (□m) or more.

Referring to FIGS. 3 and 5, the emission unit 122 is disposed in an open area of the bank 116 and its surroundings. That is, the emission unit 122 is disposed on the first electrode 121 exposed through the open area of the bank 116 and is disposed on the bank 116 and the first hollow 117. The emission unit 122 may be disposed along surfaces of the plurality of first hollows 117 on the bank 116 and the plurality of first hollows 117.

The emission unit 122 is an area where light is emitted by the coupling of electrons and holes supplied from the first electrode 121 and the second electrode 123. The emission unit 122 includes a common layer 122a disposed in the plurality of sub pixels SP and the emission layer 122b.

The common layer 122a is a layer which is disposed so as to improve the luminous efficiency of the emission layer. The common layer 122a may be formed as one layer over the plurality of sub pixels SP.

Referring to FIG. 5, the common layer 122a includes a first hole injection layer 122a_1, a first hole transport layer 122a_3, and a first electron transport layer 122a_5. For example, the first hole injection layer 122a_1, the first hole transport layer 122a_3, and the first electron transport layer 122a_5 are disposed on the plurality of first hollows 117.

The first hole injection layer 122a_1 is disposed on the first electrode 121. The first hole injection layer 122a_1 serves to smoothly inject the holes. The first hole injection layer is formed of one or more materials of HATCN(1,4,5,8,9,11-hexaazatriphenylene-hexanitrile), CuPc(cupper phthalocyanine), PEDOT(poly(3,4)-ethylenedioxythiophene), PANI(polyaniline) and NPD(N,N-dinaphthyl-N,N′-diphenylbenzidine), TPD(N,N′-Bis(3-methylphenyl)-N,N″-bis(phenyl)-benzidine), α-NPB(Bis[N-(1-naphthyl)-N-phenyl]benzidine), TDAPB(1,3,5-tris(4-diphenylaminophenyl)benzene), TCTA(Tris(4-carbazoyl-9-yl)triphenylamine), spiro-TAD(2,2′,7,7″-Tetrakis(N,N-diphenylamino)-9,9-spirobifluorene), and CBP(4,4′-bis(carbazol-9-yl) biphenyl), but is not limited thereto.

The first hole transport layer 122a_3 is disposed on the first hole injection layer 122a_1. The first hole transport layer 122a_3 serves to smoothly transport the holes. The first hole transport layer may be formed of any one or more of NPD(N,N-dinaphthyl-N,N′-bis(phenyl)-2,2′-diphenylbenzidine), TPD(N,N′-bis-(3-methylphenyl)-N,N′-bis-(phenyl)-benzidine), spiro-TAD (2,2′,7,7″-Tetrakis(N,N-diphenylamino)-9,9-spirobifluorene), and MTDATA(4,4′,4″-Tris(N-3-methylphenyl-N-phenyl-amino)-triphenylamine), but is not limited thereto.

The first electron transport layer 122a_5 is disposed on the first hole transport layer 122a_3 and the emission layer 122b. The first electron transport layer 122a_5 serves to transport and inject electrons. The first electron transport layer is formed of any one or more of Liq(8-hydroxyquinolinolato-lithium), Alq3(tris(8-hydroxyquinolinato)aluminum), PBD(2-(4-biphenylyl)-5-(4-tert-butylpheny)-1,3,4oxadiazole), TAZ(3-(4-biphenyl)4-phenyl-5-tert-butylphenyl-1,2,4-triazole), spiro-PBD, and BAlq(bis(2-methyl-8-quinolinolate)-4-(phenylphenolato)aluminum), but is not limited thereto.

In the meantime, even though it is illustrated in FIG. 5 that the common layer 122a includes the first hole injection layer 122a_1, the first hole transport layer 122a_3, and the first electron transport layer 122a_5, it is not limited thereto and further includes a hole blocking layer HBL and an electron blocking layer EBL. The hole blocking layer HBL serves to block movement of holes and the electron blocking layer EBL serves to block movement of electrons.

The emission layer 122b is a layer which emits light having a specific color and different emission layers may be disposed in each of a first sub pixel SP1, a second sub pixel SP2, and a third sub pixel SP3. For example, a red emission layer is disposed in the first sub pixel SP1, a green emission layer is disposed in the second sub pixel SP2, and a blue emission layer is disposed in the third sub pixel SP3. Further, the emission layer 122b is disposed between the first hole transport layer 122a_3 and, the first electron transport layer 122a_5 and the bank 116. Specifically, the emission layer 122b is disposed only in a part exposed through the open area of the bank 116 while being disposed between the first hole transport layer 122a_3 and the first electron transport layer 122a_5.

Referring to FIG. 4 again, the common layer 122a which is formed as one layer over all the plurality of sub pixels SP may be disposed along the surface of the plurality of first hollows 117 while covering an upper portion of the first electrode 121 and a side surface of the bank 116. Accordingly, the common layer 122a may be windingly formed along a shape of the plurality of first hollows 117 disposed on a top surface of the bank 116. As described above, as the common layer 122a is windingly formed, a length is increased as compared with an example that does not have the plurality of first hollows 117 and a resistance is increased.

The second electrode 123 may be disposed on the emission unit 122. That is, the emission unit 122 and the second electrode 123 may be disposed on the plurality of first hollows 117 on the bank 116. In the meantime, the second electrode 123 may be formed as one layer over the plurality of sub pixels SP. That is, the second electrodes 123 of the plurality of sub pixels SP are connected to be integrally formed. For example, the second electrode 123 may be a cathode and supplies electrons to the emission unit 122 so that the second electrode may be formed of a conductive material having a low work function. For example, the second electrode 123 is formed of a transparent conductive material, such as indium tin oxide (ITO) or indium zinc oxide (IZO) or magnesium (Mg), silver (Ag), ytterbium (Yb), or an alloy thereof, but is not limited thereto. In the meantime, even though it is not illustrated in the drawing, the second electrode 123 is electrically connected to a low potential power line to be supplied with a low potential power signal.

In the exemplary embodiment, the second electrode 123 is disposed along the surface of the plurality of first hollows 117. Accordingly, the second electrode 123 is disposed along the surface of the common layer 122a disposed below the second electrode 123 to be windingly formed. The exemplary embodiments of the present disclosure are not limited thereto.

Therefore, the light emitting diode 120 may be formed by the first electrode 121, the emission unit 122, and the second electrode 123.

The encapsulation unit 118 is disposed on the above-described light emitting diode 120.

The encapsulation unit 118 may have a single layer structure or a multi-layered structure. For example, the encapsulation unit 118 may include a first encapsulation layer 118a, a second encapsulation layer 118b, and a third encapsulation layer 118c.

At this time, the first encapsulation layer 118a and the third encapsulation layer 118c are configured by inorganic films and the second encapsulation layer 118b is configured by an organic film. Among the first encapsulation layer 118a, the second encapsulation layer 118b, and the third encapsulation layer 118c, the second encapsulation layer 118b is the thickest and serves as a planarization layer.

The first encapsulation layer 118a is disposed on the second electrode 123 and is disposed to be the most adjacent to the light emitting diode 120. The first encapsulation layer 118a is formed of an inorganic insulating material on which low-temperature deposition may be performed. For example, the first encapsulation layer 118a is configured by silicon nitride (SiNₓ), silicon oxide (SiOₓ), silicon oxynitride (SiON), or aluminum oxide (Al₂O₃). The first encapsulation layer 118a is deposited under a low temperature atmosphere so that during the deposition process, the damage of the emission unit 122 including an organic material which is vulnerable to the high temperature atmosphere may be suppressed.

The second encapsulation layer 118b may be formed to have a smaller area than that of the first encapsulation layer 118a. In this case, the second encapsulation layer 118b may be formed to expose both ends of the first encapsulation layer 118a. The second encapsulation layer 118b may serve as a buffer to alleviate stress between the layers due to bending of the flexible display apparatus and to enhance planarization performance.

For example, the second encapsulation layer 118b is formed of an organic insulating material, such as acrylic resin, epoxy resin, polyimide, polyethylene, or silicon oxy carbon (SiOC). For example, the second encapsulation layer 118b may be formed by an inkjet method, but is not limited thereto.

The third encapsulation layer 118c may be formed above the substrate 110 on which the second encapsulation layer 118b is formed so as to cover upper surfaces and side surfaces of each of the second encapsulation layer 118b and the first encapsulation layer 118a. At this time, the third encapsulation layer 118c may minimize or block the permeation of external moisture or oxygen into the first encapsulation layer 118a and the second encapsulation layer 118b. For example, the third encapsulation layer 118c is configured by an inorganic insulating material, such as silicon nitride (SiNₓ), silicon oxide (SiOₓ), silicon oxynitride (SiON), or aluminum oxide (Al₂O₃).

The touch sensing unit may be disposed on the encapsulation unit 118. For example, a touch buffer layer 131a is disposed on the third encapsulation layer 118c and a touch electrode is disposed on the touch buffer layer 131a.

The touch electrode may include a touch sensor metal TS and a bridge metal BRG located on different layers. A touch interlayer insulating layer 131b is disposed between the touch sensor metal TS and the bridge metal BRG.

The touch interlayer insulating layer 131b is formed of an organic material or is formed of an inorganic material. Further, the touch interlayer insulating layer may be formed with a structure in which the inorganic layer and the organic layer are laminated.

The touch buffer layer 131a and the touch interlayer insulating layer 131b are disposed to remove a step of a location where the touch electrode is disposed and be electrically insulated.

A plurality of color filters CF may be disposed on the touch sensing unit. For example, the third buffer layer 133 is disposed on the touch interlayer insulating layer 131b and the touch sensor metal TS and the color filter CF is disposed on the third buffer layer 133. The plurality of color filters CF includes a first color filter CF1, a second color filter CF2, and a third color filter CF3 which filter light with different colors. For example, the first color filter CF1 is a red color filter, the second color filter CF2 is a green color filter, and the third color filter CF3 is a blue color filter, but is not limited thereto.

Further, a black matrix BM is disposed between the plurality of color filters CF. The black matrix may be disposed to overlap the touch electrode disposed between the plurality of color filters CF.

The third planarization layer 135 may be disposed on the plurality of color filters CF and the black matrix BM. The third planarization layer 135 is an organic layer which planarizes and protects tops of the plurality of color filters CF and the black matrix BM. For example, the third planarization layer 135 may be formed of an organic material such as acryl resin, epoxy resin, phenolic resin, polyamide resin, or polyimide resin,

The cover glass 139 is bonded onto the third planarization layer 135 by the adhesive layer 137. The adhesive layer 137 serves to adhere the components of the display apparatus 100 to each other, and for example, may be formed using an optically clear display adhesive, such as an optical clear adhesive (OCR) or an optical clear resin (OCR) but is not limited thereto.

The cover glass 139 protects the component of the display apparatus 100 from the external shocks and suppresses damages such as a scratch.

For example, the common layer of the plurality of light emitting diodes is formed as one layer over the plurality of sub pixels. The light emitting diodes of the plurality of sub pixels are formed to share the common layer so that when a light emitting diode of a specific sub pixel emits light, current leakage that the current flows to a light emitting diode of an adjacent sub pixel may occur. For example, when only the red sub pixel, among the plurality of sub pixels, emits light, a part of current which is supplied to drive a light emitting diode of the red sub pixel may be leaked to adjacent green sub pixel and blue sub pixel through the common layer. That is, due to the current leakage, a light emitting diode of an unintended sub pixel emits light and color mixture between the plurality of sub pixels may be caused. Further, color abnormality and spots are visibly recognized due to the leakage current so that a display quality is degraded.

Specifically, during the low grayscale driving, a luminance of light emitted from a sub pixel which is being driven is low so that light emitted from the adjacent sub pixels may be more easily perceived. That is, during the low grayscale driving, color abnormality and spot defects due to the leakage current are more easily perceived, which may cause serious degradation in the display quality.

In the meantime, generally, the display apparatus includes a bank for defining each sub pixel and the bank of the display apparatus may be formed of a transparent material. Light which is transmitted from the outside by means of the transparent bank is reflected from a metal material below the bank so that there is a problem in that the reflection of the display apparatus by the external light is increased.

In the meantime, in order to reduce or minimize the leakage current, a structure in which a trench structure is formed in the bank may be used. However, when the trench structure is formed in the bank as described above, a bank having partially different thickness may be used. In this case, the spot due to the external light reflection caused by the thickness difference of the bank may be visible to the user.

In the display apparatus 100 according to the exemplary embodiment of the present disclosure, the plurality of first hollows 117 is disposed between the plurality of sub pixels SP to reduce or minimize leakage current through the common layer 122a of the emission unit 122 of the light emitting diode 120.

For example, the plurality of first hollows 117 is disposed between the plurality of sub pixels SP to increase the length of the common layer 122a of the emission unit 122 which is a flowing path of the leakage current, resulting in the increase the length of the flowing path of the leakage current. Therefore, as the length of the flowing path of the leakage current increases, the resistance increases so that the leakage current which flows to the adjacent sub pixel SP is reduced or minimized. Accordingly, in the display apparatus 100 according to the exemplary embodiment of the present disclosure, the plurality of first hollows 117 is disposed between the plurality of sub pixels SP to reduce or minimize visual recognition of the color abnormality or spots due to the leakage current and improve the display quality of the display apparatus 100.

Further, in the display apparatus 100 according to the exemplary embodiment of the present disclosure, the external light reflection is reduced or minimized. When light is incident from the outside of the display apparatus 100, external light reflection may be caused by the metal material disposed in the display apparatus 100. Specifically, as in the display apparatus 100 according to the exemplary embodiment of the present disclosure, when the bank 116 which is formed of a transparent material is used, the external light reflection may be caused by the metal material disposed below the bank 116. Therefore, in the display apparatus 100 according to the exemplary embodiment of the present disclosure, the plurality of first hollows 117 is disposed above the bank 116 to scatter external light which is incident from the outside. Therefore, an amount of external light which reaches the metal material disposed below the bank 116 is reduced. For example, even though external light reaches the metal material disposed below the bank 116 to be reflected, reflected light is scattered by the plurality of first hollows 117 again. Accordingly, in the display apparatus 100 according to the exemplary embodiment of the present disclosure, the external light reflection is reduced or minimized.

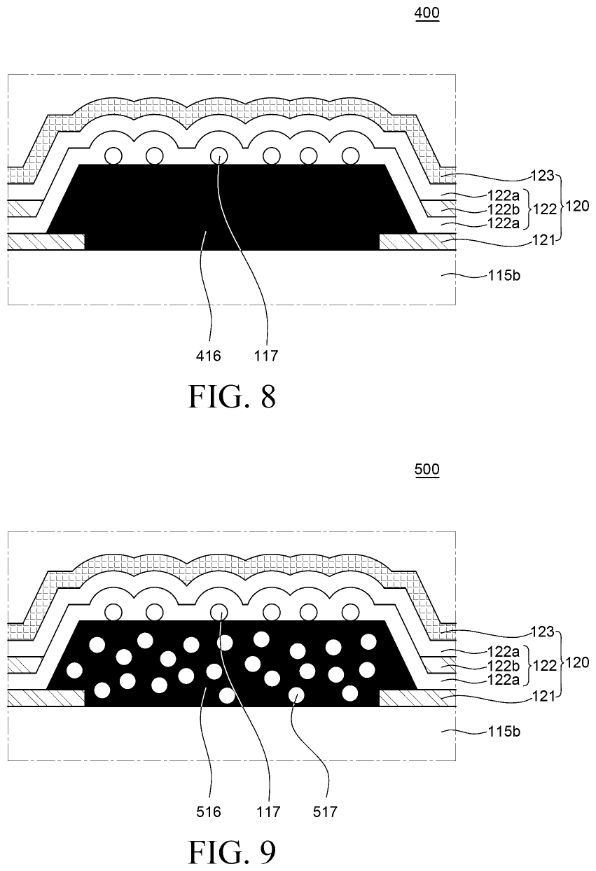

FIG. 6 is an enlarged cross-sectional view of a display apparatus according to another exemplary embodiment of the present disclosure. The only difference between a display apparatus 200 of FIG. 6 and the display apparatus 100 of FIGS. 1 to 5 is a light emitting diode 220, but the other configuration is substantially the same, so that a redundant description will be omitted.

Referring to FIG. 6, the light emitting diode 220 includes a first electrode 121, an emission unit 222, and a second electrode 123.

In the meantime, various organic light emitting diode structures for improving the efficiency and the lifespan of the organic light emitting diode and reducing power consumption are proposed to improve a quality and a productivity of the display apparatus.

Accordingly, an organic light emitting diode with a tandem structure which uses a plurality of stacks, that is, a lamination of a plurality of electroluminescent units is proposed to implement the improved efficiency and lifespan characteristic, as well as an organic light emitting diode which applies one stack, that is, one electroluminescent layer (EL layer).

In the organic light emitting diode 220 with a tandem structure, that is, a two-stack structure using a lamination of a first electroluminescent layer 222b1 and a second electroluminescent layer 222b2, an emission area in which light is emitted by means of recombination of electrons and holes is located in each of the first electroluminescent layer 222b1 and the second electroluminescent layer 222b2. The light emitted from the first electroluminescent layer 222b1 and the second electroluminescent layer 222b2 causes constructive interference to provide a higher luminance than that of the organic light emitting diode with a single stack structure.

For example, the stack structure includes a charge generation layer 223 disposed between the first electrode 121 and the second electrode 123, a first stack disposed between the charge generation layer 223 and the first electrode 121, and a second stack disposed between the second electrode 123 and the charge generation layer 223. Each of the first stack and the second stack includes a common layer 222a thereabove and therebelow, with the first electroluminescent layer 222b1 and the second electroluminescent layer 222b2 therebetween.

The emission unit 222 includes a first hole injection layer 222a_1, a first hole transport layer 222a_3, a second hole transport layer 222a_5, and a first electron transport layer 222a_7 which are a common layer 222a. Further, the emission unit 222 includes the first electroluminescent layer 222b1 and the second electroluminescent layer 222b2.

The emission unit 222 with the two-stack structure is disposed by laminating the first hole injection layer 222a_1 on the first electrode 121, the first hole transport layer 222a_3 on the first hole injection layer 222a_1, the first electroluminescent layer 222b1 on the first hole transport layer 222a_3, the second hole transport layer 222a_5 on the first electroluminescent layer 222b1, the second electroluminescent layer 222b2 on the second hole transport layer 222a_5, and the first electron transport layer 222a_7 on the second electroluminescent layer 222b2 in this order.

The first hole injection layer 222a_1 serves to smoothly inject the holes. The first hole injection layer 222a_1 is formed of one or more materials of HATCN(1,4,5,8,9,11-hexaazatriphenylene-hexanitrile), CuPc(cupper phthalocyanine), PEDOT(poly(3,4)-ethylenedioxythiophene), PANI(polyaniline) and NPD(N,N-dinaphthyl-N,N′-diphenylbenzidine), TPD(N,N′-Bis(3-methylphenyl)-N,N″-bis(phenyl)-benzidine), α-NPB(Bis[N-(1-naphthyl)-N-phenyl]benzidine), TDAPB(1,3,5-tris(4-diphenylaminophenyl)benzene), TCTA(Tris(4-carbazoyl-9-yl)triphenylamine), spiro-TAD(2,2′,7,7″-Tetrakis(N,N-diphenylamino)-9,9-spirobifluorene) and CBP(4,4′-bis(carbazol-9-yl)biphenyl), but is not limited thereto.

The first hole transport layer 222a_3 and the second hole transport layer 222a_5 serve to smoothly transport the holes. The first hole transport layer 222a_3 and the second hole transport layer 222a_5 may be formed of any one or more of NPD(N,N-dinaphthyl-N,N′-bis(phenyl)-2,2′-diphenylbenzidine), TPD(N,N′-bis-(3-methylphenyl)-N,N′-bis-(phenyl)-benzidine), spiro-TAD(2,2′,7,7″-Tetrakis(N,N-diphenylamino)-9,9-spirobifluorene), and MTDATA(4,4′,4″-Tris(N-3-methylphenyl-N-phenyl-amino)-riphenylamine), but is not limited thereto.

The charge generation layer 223 is disposed between the first stack and the second stack to generate charges. Specifically, the charge generation layer 223 is disposed between the first electroluminescent layer 222b1 and the second electroluminescent layer 222b2. The charge generation layer 223 includes an N-type charge generation layer 223a and a P-type charge generation layer 223b which generate positive charges and negative charges in both directions. The N-type charge generation layer 223a is disposed on the second hole transport layer 222a_5 and the P-type charge generation layer 223b is disposed between the N-type charge generation layer 223a and the second electroluminescent layer 222b2. The charge generation layer 223 may be configured by a plurality of layers including the N-type charge generation layer 223a and the P-type charge generation layer 223b, but is not limited thereto and may be configured as a single layer.

The N-type charge generation layer 223a injects electrons into the first electroluminescent layer 222b1. The first N-type charge generation layer 223a may include an N-type dopant material and an N-type host material. The N-type dopant material may be a metal of Group 1 and Group 2 on the periodic table, an organic material which may inject the electrons, or a mixture thereof. For example, the N-type dopant material may be any one of an alkali metal and an alkaline earth metal. That is, the N-type charge generation layer 223a may be formed of an organic layer doped with an alkali metal such as lithium (Li), sodium (Na), potassium (K), or cesium (Cs) or an alkali earth metal such as magnesium (Mg), strontium (Sr), barium (Ba), or radium (Ra), but is not limited thereto. The N-type host material may be formed of a material which is capable of transmitting electrons, for example, may be formed of any one or more of Alq3(tris(8-hydroxyquinolino)aluminum), Liq(8-hydroxyquinolinolato-lithium), PBD(2-(4-biphenylyl)-5-(4-tert-butylphenyl)-1,3,4oxadiazole), TAZ(3-(4-biphenyl)4-phenyl-5-tertbutylphenyl-1,2,4-triazole), spiro-PBD, and BAlq(bis(2-methyl-8-quinolinolate)-4-(phenylphenolato)aluminium), SAlq, TPBi(2.2′,2-(1,3,5-benzinetriyl)-tris(1-phenyl-1-H-benzimidazole), oxadiazole, triazole, phenanthroline, benzoxazole, and benzthiazole, but is not limited thereto.

The P-type charge generation layer 223b injects holes into the second electroluminescent layer 222b2. The first P-type charge generation layer 223b may include a P-type dopant material and a P-type host material. The P-type dopant material may be formed of metal oxide, an organic material such as tetrafluoro-tetracyanoquinodimethane (F4-TCNQ), HAT-CN (Hexaazatriphenylene-hexacarbonitrile), or hexaazatriphenylene, or a metal material such as V₂O₅, MoOₓ, and WO₃, but is not limited thereto. The P-type host material may be formed of a material which is capable of transmitting holes, for example, may be formed of a material including any one or more of NPD(N,N-dinaphthyl-N,N′-diphenyl benzidine)(N,N′-bis(naphthalene-1-yl)-N,N′-bis (phenyl)-2,2′-dimethylbenzidine), TPD(N,N′-bis-(3-methylphenyl)-N,N′-bis-(phenyl)-benzidine), and MTDATA(4,4′,4-Tris(N-3-methylphenyl-N-phenyl-amino)-triphenylamine), but is not limited thereto. The first electroluminescent layer 222b1 and the second electroluminescent layer 222b2 serve to emit light by combination of holes and electrons and include emission materials which emit red light, green light, and blue light. The emission materials may be formed using a phosphorescent material or a fluorescent material.

The first electron transport layer 222a_7 serves to transport and inject electrons. The first electron transport layer 222a_7 may be formed of any one or more of Liq(8-hydroxyquinolinolato-lithium), Alq3(tris(8-hydroxyquinolinato) aluminum), PBD(2-(4-biphenylyl)-5-(4-tert-butylpheny)-1,3,4oxadiazole), TAZ(3-(4-biphenyl)4-phenyl-5-tert-butylphenyl-1,2,4-triazole), spiro-PBD, and BAlq(bis(2-methyl-8-quinolinolate)-4-(phenylphenolato) aluminum), but is not limited thereto.

At this time, the first hole injection layer 222a_1, the first hole transport layer 222a_3, the second hole transport layer 222a_5, and the first electron transport layer 222a_7 which are the common layer 222a are integrally disposed along a surface of the plurality of first hollows 117 disposed on top surfaces of the first electrode 121 and the bank 116. The first electroluminescent layer 222b1 and the second electroluminescent layer 222b2 are disposed between the banks 116.

In the display apparatus 200 according to another exemplary embodiment of the present disclosure, leakage current generated between adjacent sub pixels may be effectively blocked. That is, in the display apparatus 200 according to another exemplary embodiment of the present disclosure, the plurality of first hollows 117 is disposed to increase resistance of the emission layer 122 between adjacent sub pixels SP and increase a leakage current path, thereby reducing the leakage current.

For example, in the display apparatus 200 according to another exemplary embodiment of the present disclosure, the plurality of first hollows 117 is disposed above the bank 116 which is formed of a transparent material to scatter external light incident from the outside and external light which is reflected from the metal material disposed below the bank 116. Accordingly, in the display apparatus 200 according to another exemplary embodiment of the present disclosure, the external light reflection is reduced or minimized.

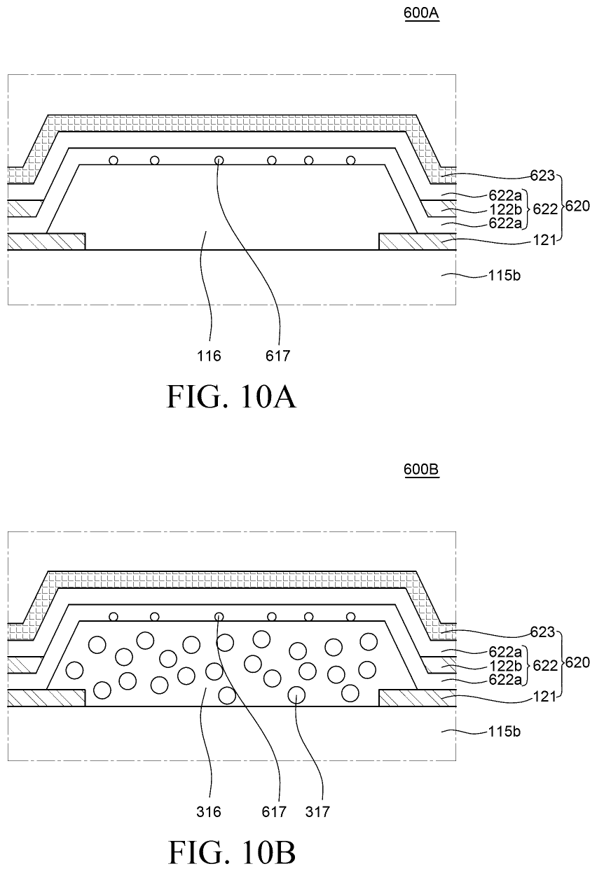

FIG. 7 is an enlarged cross-sectional view of a display apparatus according to still another exemplary embodiment of the present disclosure. The only difference between a display apparatus 300 of FIG. 7 and the display apparatus 100 of FIGS. 1 to 5 is a bank 316, but the other configuration is substantially the same, so that a redundant description will be omitted.

Referring to FIG. 7, the bank 316 includes a plurality of second hollows 317 therein. At this time, the plurality of second hollows 317 may be irregularly dispersed in the bank 316.

In the display apparatus 300 according to still another exemplary embodiment of the present disclosure, a leakage current is effectively blocked. That is, in the display apparatus 300 according to still another exemplary embodiment of the present disclosure, the plurality of first hollows 117 is disposed to increase resistance of the emission layer 122 between adjacent sub pixels SP and increase a leakage current path, thereby reducing the leakage current.

Further, in the display apparatus 300 according to still another exemplary embodiment of the present disclosure, the plurality of first hollows 117 is disposed above the bank 316 which is formed of a transparent material to scatter external light incident from the outside and external light which is reflected from the metal material disposed below the bank 316. Accordingly, in the display apparatus 300 according to still another exemplary embodiment of the present disclosure, the external light reflection is reduced or minimized.

Further, the display apparatus 300 according to still another exemplary embodiment of the present disclosure includes a plurality of second hollows 317 in the bank 316 to scatter light transmitted from the outside. Specifically, the bank 316 including a plurality of second hollows 317 is disposed to scatter light incident from the outside by the plurality of second hollows 317 in the bank and thus reduce external light which is incident to the metal material below the bank 316. For example, even though external light is reflected from the metal material below the bank 316, the light is scattered by the plurality of second hollows 317 again. Accordingly, in the display apparatus 300 according to still another exemplary embodiment of the present disclosure, light which is incident as external light is scattered by the plurality of second hollows 317 to reduce or minimize visual recognition of the external light.

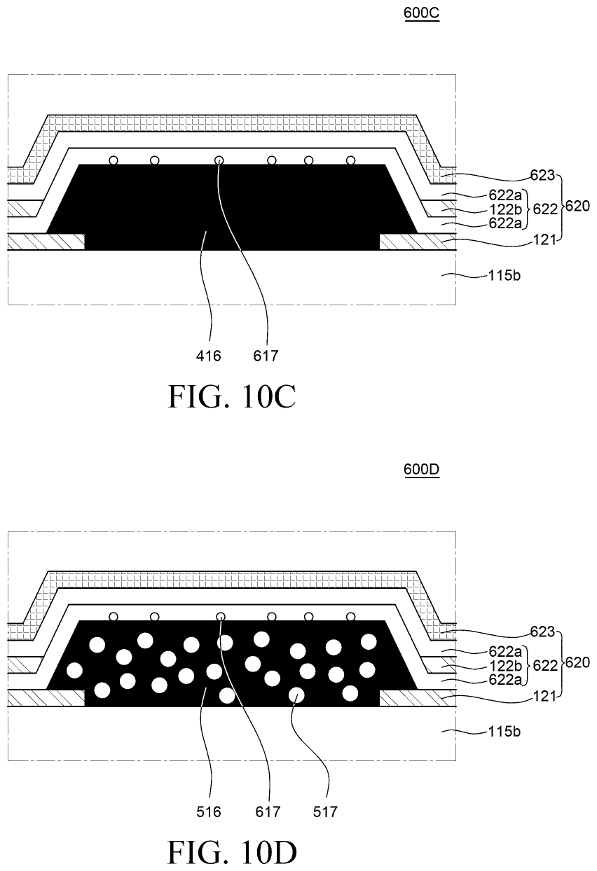

FIG. 8 is an enlarged cross-sectional view of a display apparatus according to still another exemplary embodiment of the present disclosure. The only difference between a display apparatus 400 of FIG. 8 and the display apparatus 100 of FIGS. 1 to 5 is a bank 416, but the other configuration is substantially the same, so that a redundant description will be omitted.

Referring to FIG. 8, the bank 416 includes a black material. The black material is configured by an organic material or an inorganic material. The black material may be configured by a carbon based material or a metal oxide. The bank 416 includes 4,4-thiodibenzenethiol (TDT) based epoxy acrylate.

In the display apparatus 400 according to still another exemplary embodiment of the present disclosure, leakage current generated between adjacent sub pixels may be effectively blocked. That is, the plurality of first hollows 117 of the present disclosure is disposed to increase resistance of the emission layer 122 between adjacent sub pixels SP and increase a leakage current path, thereby reducing the leakage current.

Further, in the display apparatus 400 according to still another exemplary embodiment of the present disclosure, the bank 416 includes a black material to block external light reflection. For example, light incident from the outside is absorbed by the bank 416 of the black material and the external light which is incident onto the metal material below the bank 416 is reduced. Accordingly, in the display apparatus 400 according to still another exemplary embodiment of the present disclosure, external light reflection is blocked by the bank 416 of a black material.

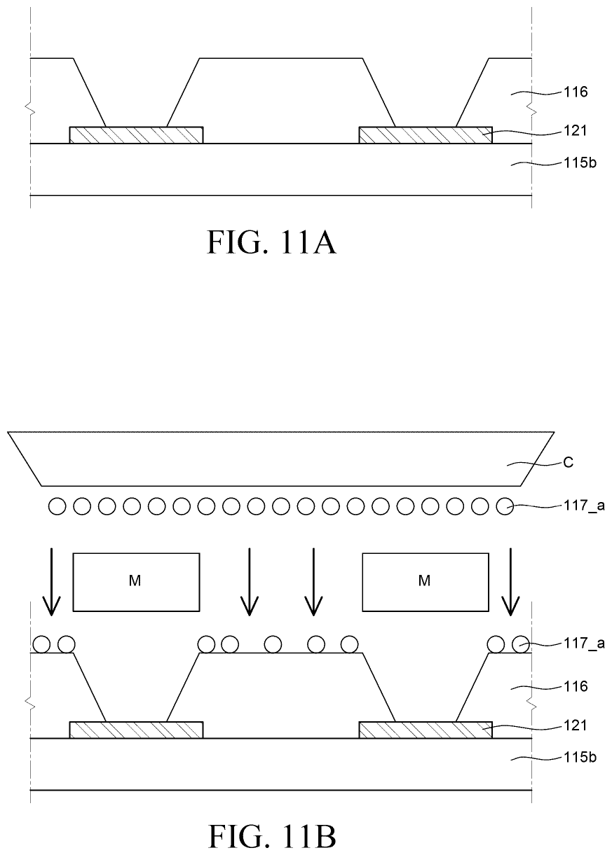

FIG. 9 is an enlarged cross-sectional view of a display apparatus according to still another exemplary embodiment of the present disclosure. The only difference between a display apparatus 500 of FIG. 9 and the display apparatus 400 of FIG. 8 is a bank 516, but the other configuration is substantially the same, so that a redundant description will be omitted.

Referring to FIG. 9, the bank 516 includes a plurality of third hollows 517 therein. At this time, the plurality of third hollows 517 may be irregularly dispersed in the bank 516.

In the display apparatus 500 according to still another exemplary embodiment of the present disclosure, leakage current generated between adjacent sub pixels may be effectively blocked. That is, the plurality of first hollows 117 of the present disclosure is disposed in the display apparatus 500 to increase resistance of the emission layer 122 between adjacent sub pixels SP and increase a leakage current path, thereby reducing the leakage current.

Further, in the display apparatus 500 according to still another exemplary embodiment of the present disclosure, the bank 516 includes a black material to block external light reflection. Specifically, light incident from the outside is absorbed by the bank 516 of the black material and the external light which is incident onto the metal material below the bank 516 is reduced. Accordingly, in the display apparatus 500 according to still another exemplary embodiment of the present disclosure, external light reflection is blocked by the bank 516 of a black material.

In the display apparatus 500 according to still another exemplary embodiment of the present disclosure, a bank 516 including the plurality of third hollows 517 is disposed to block light incident from the outside to reduce external light which is incident onto the metal material below the bank 517. Further, even though the external light is reflected, the plurality of third hollows 517 scatters light again to reduce light visible to the user. Accordingly, in the display apparatus 500 according to still another exemplary embodiment of the present disclosure, light which is incident as external light is scattered to reduce or minimize visual recognition of the external light.

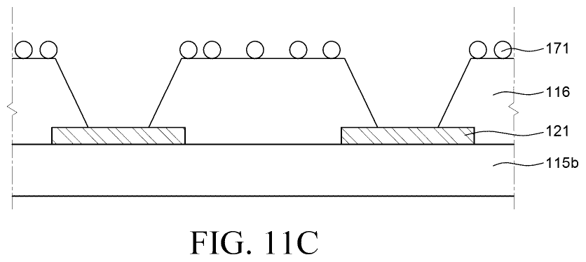

FIGS. 10A to 10D are enlarged cross-sectional views of a display apparatus according to various exemplary embodiments of the present disclosure. The only difference between a display apparatus 600A of FIG. 10A and the display apparatus 100 of FIG. 3 is a light emitting diode 620, a first hollows 617, an emission unit 622, and a second electrode 623, but the other configurations are substantially the same, so that a redundant description will be omitted. The only difference between a display apparatus 600B of FIG. 10B and the display apparatus 300 of FIG. 7 is a light emitting diode 620, a first hollows 617, an emission unit 622, and a second electrode 623, but the other configurations are substantially the same, so that a redundant description will be omitted. The only difference between a display apparatus 600C of FIG. 10C and the display apparatus 400 of FIG. 8 is a light emitting diode 620, a first hollows 617, an emission unit 622, and a second electrode 623, but the other configurations are substantially the same, so that a redundant description will be omitted. The only difference between a display apparatus 600D of FIG. 10D and the display apparatus 500 of FIG. 9 is a light emitting diode 620, a first hollows 617, an emission unit 622, and a second electrode 623, but the other configurations are substantially the same, so that a redundant description will be omitted.

Referring to FIGS. 10A to 10D, the first hollows 617 are disposed on top surfaces of banks 116, 316, 416, and 516. At this time, the first hollow 617 may have a diameter in nanometers (nm) or less. Accordingly, the diameter of the first hollow 617 is sufficiently small so that the emission unit 622 and the second electrode 623 disposed on the banks 116, 316, 416, and 516 and the first hollow 617 have flat top surfaces.

In the meantime, in the display apparatuses 600A, 600B, 600C, and 600D according to various exemplary embodiments of the present disclosure, a bottom surface of the common layer 622a which is formed as one layer over the plurality of sub pixels SP is windingly formed along the surface of the first hollow 617. Therefore, the common layer 622a is disposed along the surfaces of the plurality of first hollows 617 while covering a top of the first electrode 121 and side surfaces of the banks 116, 316, 416, and 516. That is, the bottom surface of the common layer 622a may be windingly formed along a shape of the plurality of first hollows 617 disposed on top surfaces of the banks 116, 316, 416, and 516. As described above, as the bottom surface of the common layer 622a is windingly formed, a length is increased as compared with an example that does not have the plurality of first hollows 617 and a resistance is increased. As a result, the length of the common layer 622a of the emission unit 622 which is a flowing path of the leakage current is increased to increase the path through which the leakage current flows. Therefore, as the length of the path through which the leakage current flows increase, the resistance increases so that the leakage current which flows to the adjacent sub pixel SP is reduced or minimized.

In the display apparatuses 600A, 600B, 600C, and 600D according to various exemplary embodiments of the present disclosure, the plurality of first hollows 617 is disposed between the plurality of sub pixels SP to reduce or minimize visual recognition of the color abnormality or spots due to the leakage current and improve the display quality of the display apparatuses 600A, 600B, 600C, and 600D.

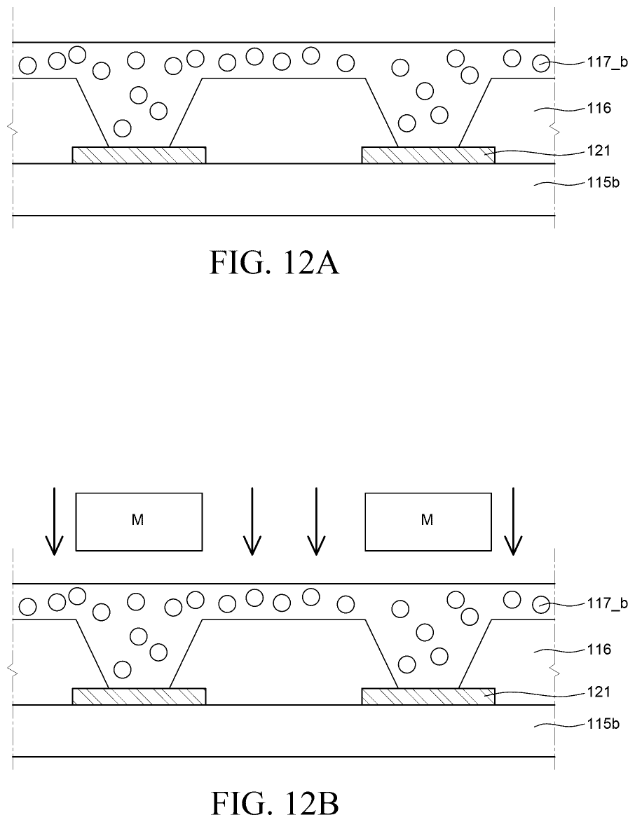

FIGS. 11A to 11C are process cross-sectional views for explaining a manufacturing method of a display apparatus according to an exemplary embodiment of the present disclosure. In FIGS. 11A to 11C, before forming the emission unit 122 and the second electrode 123 on the first electrode 121 and the bank 116, a process of forming the first hollow 117 on the bank 116 is illustrated.

Referring to FIG. 11A, the first electrode 121 is formed on the second planarization layer 115b and the bank 116 is formed on the first electrode 121. At this time, the bank 116 is disposed on one side of the first electrode 121 on the second planarization layer 115b to expose a part of the first electrode 121.

Referring to FIG. 11B, a hollow silica 117_a is sprayed and coated on the bank 116 which exposes a part of the first electrode 121 with aerogel using a mask M. Specifically, the aerogel based hollow silica 117_a is sprayed using a coater C to be coated in an area excluding an area where the mask M is disposed. That is, the aerogel based hollow silica 117_a is coated on the top surface of the bank 116.

At this time, the mask M is provided to form the first hollow 117 in an area excluding an area from which the first electrode 121 is exposed and suppresses the hollow silica 117_a from being coated in an area of the bank 116 from which the first electrode 121 is exposed and the side surface of the bank 116.

Referring to FIG. 11C, the formation of the plurality of first hollows 117 on the top surface of the bank 116 excluding an area of the bank 116 from which the first electrode 121 is exposed and the side surface of the bank 116 is completed by performing the aerogel coating spray process. At this time, the plurality of first hollows 117 may be irregularly or regularly disposed on the bank 116.

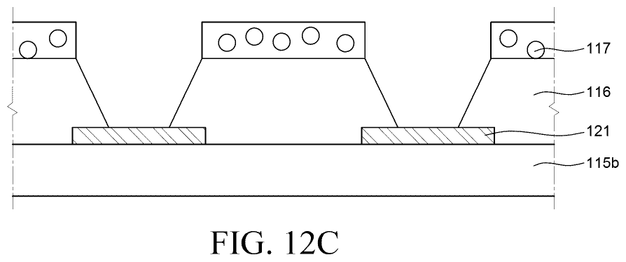

FIGS. 12A to 12C are process cross-sectional views for explaining a manufacturing method of a display apparatus according to another exemplary embodiment of the present disclosure.

In FIGS. 12A to 12C, before forming the emission unit 122 and the second electrode 123 on the first electrode 121 and the bank 116, a process of forming the first hollow 117 on the bank 116 is illustrated.

First, a hollow photoresist solution 117_b is prepared by mixing hollow silica in polymer resin.

Referring to FIG. 12A, the hollow photoresist solution 117_b is applied above the first electrode 121 and the bank 116 formed on the second planarization layer 115b.

Referring to FIG. 12B, the bank 116 on which the hollow photoresist solution 117b is applied is exposed using the mask M. Specifically, a part exposed from the mask M is exposed and the hollow photoresist solution 117_b is maintained in a part masked by the mask M as it is. Thereafter, the photoresist solution 117_b which is not exposed is removed by a development process. The exposed hollow photoresist solution 117_b is cured by a curing process.

Referring to FIG. 12C, the formation of the plurality of first hollows 117 on the top surface of the bank 116 excluding an area of the bank 116 from which the first electrode 121 is exposed and the side surface of the bank 116 is completed by performing the photo process. At this time, the plurality of first hollows 117 may be irregularly or regularly disposed on the bank 116.

The exemplary embodiments of the present disclosure can also be described as follows:

According to an aspect of the present disclosure, there is provided a display apparatus. The display apparatus comprises a substrate on which a plurality of sub pixels are defined, a plurality of light emitting diodes, each of which is disposed in each of the plurality of sub pixels and includes a first electrode, an emission unit, and a second electrode, a bank which is disposed on one side of the first electrode on the substrate to expose a part of the first electrode, and, a plurality of first hollows disposed on the bank, wherein the emission unit and the second electrode are disposed on the plurality of first hollows sequentially.

The bank may include a top surface and a side surface and the plurality of first hollows is disposed on the top surface of the bank.

The bank may include a plurality of second hollows therein.

The bank may include a black material.

The bank may include a plurality of third hollows therein.

The plurality of first hollows may be irregularly disposed on the bank.

The emission unit may be disposed along surfaces of the plurality of first hollows on the bank and the plurality of first hollows.

The emission unit may include a first hole injection layer, a first hole transport layer on the first hole injection layer, a first emission layer on the first hole transport layer, a first electron transport layer on the first emission layer, and a first electron injection layer on the first electron transport layer.

The first hole injection layer, the first hole transport layer, the first electron transport layer, and the first electron injection layer may be disposed on the plurality of first hollows, and the first emission layer may be disposed between the banks.

The emission unit may further include a second hole transport layer disposed between the first emission layer and the first electron transport layer, and a second emission layer disposed between the second hole transport layer and the first electron transport layer.

The first hole injection layer, the first hole transport layer, the first electron transport layer, the first electron injection layer, and the second hole transport layer may be disposed on the plurality of first hollows, and the second emission layer may be disposed between the banks.

The emission unit may further include a charge generation layer disposed between the first emission layer and the second emission layer.

The bank may have a surface roughness.

The plurality of first hollows may be hollow spheres.

The first hole injection layer, the first hole transport layer and the first electron transport layer may be disposed along a surface of the plurality of first hollows and covering an upper portion of the first electrode and a side surface of the bank.

The first hole injection layer, the first hole transport layer, the first electron transport layer and the second hole transport layer may be disposed along a surface of the plurality of first hollows and covering an upper portion of the first electrode and a side surface of the bank.

The plurality of second hollows may be irregularly disposed in the bank.

The plurality of third hollows may be irregularly disposed in the bank.

According to another aspect of the present disclosure, there is provided a display apparatus. The display apparatus comprises: a substrate; a plurality of sub pixels disposed on the substrate; a bank disposed between the plurality of sub pixels, a part of the bank corresponding to emission areas of the plurality sub pixels including an open area; and a plurality of first hollows disposed on the bank and between the plurality of sub pixels.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a substrate on which a plurality of sub pixels is defined;
a plurality of light emitting diodes, each of which is disposed in each of the plurality of sub pixels and includes a first electrode, an emission unit, and a second electrode;
a bank which is on one side of the first electrode on the substrate to expose a part of the first electrode; and
a plurality of first hollows on the bank,
wherein the emission unit and the second electrode are on the plurality of first hollows sequentially.

2. The display apparatus according to claim 1, wherein the bank includes a top surface and a side surface and the plurality of first hollows is on the top surface of the bank.

3. The display apparatus according to claim 1, wherein the bank includes a plurality of second hollows therein.

4. The display apparatus according to claim 1, wherein the bank includes a black material.

5. The display apparatus according to claim 4, wherein the bank includes a plurality of third hollows therein.

6. The display apparatus according to claim 1, wherein the plurality of first hollows is irregularly disposed on the bank.

7. The display apparatus according to claim 1, wherein the emission unit is disposed along surfaces of the plurality of first hollows on the bank and the plurality of first hollows.

8. The display apparatus according to claim 1, wherein the emission unit includes:
a first hole injection layer;
a first hole transport layer on the first hole injection layer;
a first emission layer on the first hole transport layer;
a first electron transport layer on the first emission layer; and
a first electron injection layer on the first electron transport layer.

9. The display apparatus according to claim 8, wherein the first hole injection layer, the first hole transport layer, the first electron transport layer, and the first electron injection layer are on the plurality of first hollows and the first emission layer is between the banks.

10. The display apparatus according to claim 8, wherein the emission unit further includes:
a second hole transport layer between the first emission layer and the first electron transport layer; and
a second emission layer between the second hole transport layer and the first electron transport layer.

11. The display apparatus according to claim 10, wherein the first hole injection layer, the first hole transport layer, the first electron transport layer, the first electron injection layer, and the second hole transport layer are on the plurality of first hollows and the second emission layer is between the banks.

12. The display apparatus according to claim 10, wherein the emission unit further includes a charge generation layer between the first emission layer and the second emission layer.

13. The display apparatus according to claim 1, wherein the bank has a surface roughness.

14. The display apparatus according to claim 1, wherein the plurality of first hollows are hollow spheres.

15. The display apparatus according to claim 9, wherein the first hole injection layer, the first hole transport layer and the first electron transport layer are disposed along a surface of the plurality of first hollows and covering an upper portion of the first electrode and a side surface of the bank.

16. The display apparatus according to claim 11, wherein the first hole injection layer, the first hole transport layer, the first electron transport layer and the second hole transport layer are disposed along a surface of the plurality of first hollows and covering an upper portion of the first electrode and a side surface of the bank.

17. The display apparatus according to claim 3, wherein the plurality of second hollows is irregularly disposed in the bank.

18. The display apparatus according to claim 5, wherein the plurality of third hollows is irregularly disposed in the bank.

19. A display apparatus, comprising:
a substrate;
a plurality of sub pixels on the substrate;
a bank between the plurality of sub pixels, a part of the bank corresponding to emission areas of the plurality sub pixels including an open area; and
a plurality of first hollows on the bank and between the plurality of sub pixels.

20. The display apparatus according to claim 19, wherein the bank includes a plurality of second hollows therein.
